(19) United States
(12) Patent Application Publication
(10) Pub. No.: US 2026/0161991 A1
(43) Pub. Date: Jun. 11, 2026

(54) TUNING AND TRIANGULATING TWO-LEVEL SYSTEMS WITH MULTIPLE ELECTRODES IN A SUPERCONDUCTING QUBIT ARCHITECTURE

(71) Applicant: International Business Machines Corporation, Armonk, NY (US)

(72) Inventors: Karthik Balakrishnan, Scarsdale, NY (US); Isaac Lauer, Chappaqua, NY (US); Jeffrey W. Sleight, Ridgefield, CT (US); Harry Jonathon Mamin, Palo Alto, CA (US); Daniel Rugar, Los Altos, CA (US)

(21) Appl. No.: 18/679,051

(22) Filed: May 30, 2024

(51) Int. Cl. G06N 10/70; G06N 10/40; H10N 60/01; H10N 60/80; H10N 60/82; H10N 69/00

(52) U.S. Cl. CPC G06N 10/70; G06N 10/40; H10N 60/0912; H10N 60/805; H10N 60/82; H10N 69/00

(57) ABSTRACT

An N-dimensional scan of a set of bias voltages is performed, each bias voltage defining a voltage of a corresponding electrode of a set of electrodes, the electrodes being proximate to a given qubit. A sensitivity of a performance of the given qubit to an electronic field generated by each of the electrodes is determined. A probable location of at least one two-level system (TLS) is extrapolated based on the determined sensitivities. An effect of the two-level system (TLS) on the given qubit is mitigated based on the extrapolated location.

### BACKGROUND

The present invention relates generally to the electrical, electronic and computer arts and, more particularly, to quantum computing.

A Superconducting Qubit is the basic element of a superconducting quantum computer, and can be physically instantiated in a variety of ways. It is typically an anharmonic electrical resonator. Operations on qubits generally introduce some error in quantum systems, such as some level of decoherence and/or some level of quantum noise affecting qubit availability. Such errors can include quantum noise generated by defects called two level systems (TLS). In the present context, the term TLS can refer generally to any material defect that can interact with a qubit and has a characteristic frequency that can be manipulated by an applied electric field.

T1 is the energy relaxation time of a qubit, and one of the basic coherence characterizations of a qubit. The T1 (energy relaxation time) of a qubit can fluctuate in time due to TLSs. TLSs can cause T1 relaxation times to be shorter than expected, leading to decreases in the coherence times of quantum systems. In addition to TLSs, T1 relaxation times can be negatively affected by energy leakage to the environment, an effect called Purcell loss. Decreases in the relaxation and coherence times of quantum systems can limit the ability of the quantum system to perform long quantum algorithms and can increase the error rate of quantum gate operations.

In practice, an interposer is a chip which hosts wiring and other passive components and is typically combined with the qubit chip in some kind of heterogenous integration. In this context, it includes a metallic gate that is located ‘over’ the qubit device when the chips are integrated.

### BRIEF SUMMARY

Principles of the invention provide systems and techniques for tuning and triangulating two-level systems with multiple electrodes in a superconducting qubit architecture. In one aspect, an exemplary method includes the operations of performing an N-dimensional scan of a set of bias voltages, each bias voltage defining a voltage of a corresponding electrode of a set of electrodes, the electrodes being proximate to a given qubit; determining a sensitivity of a performance of the given qubit to an electronic field generated by each of the electrodes; extrapolating a probable location of at least one two-level system (TLS) based on the determined sensitivities; and mitigating an effect of the two-level system (TLS) on the given qubit based on the extrapolated location.

In one aspect, a computer program product includes one or more tangible computer-readable storage media and program instructions stored on at least one of the one or more tangible computer-readable storage media, the program instructions executable by a processor, the program instructions including performing an N-dimensional scan of a set of bias voltages, each bias voltage defining a voltage of a corresponding electrode of a set of electrodes, the electrodes being proximate to a given qubit; determining a sensitivity of a performance of the given qubit to an electronic field generated by each of the electrodes; extrapolating a probable location of at least one two-level system (TLS) based on the determined sensitivities; and mitigating an effect of the two-level system (TLS) on the given qubit based on the extrapolated location.

In one aspect, a structure comprises a substrate; a superconducting qubit on the substrate; a plurality of electrodes terminating near different positions of the qubit; a plurality of voltage sources, where each voltage source is connected to a corresponding one of the electrodes; and a controller configured to perform an N-dimensional scan on a set of bias voltages, each bias voltage defining a voltage of a corresponding electrode of the plurality of electrodes; determine a sensitivity of a performance of the qubit to an electronic field generated by each of the electrodes; and extrapolate a location of at least one two-level system (TLS) based on the determined sensitivities.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment and/or instructions executing on a remote processor, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a diagram of a first example, non-limiting, on-chip filtering system that comprises a quantum device having a qubit device, an electrode, and an electrical filter, in accordance with example embodiments;

FIG. 2 is a diagram of a second example, non-limiting, on-chip filtering system that comprises a quantum device having a qubit device, an electrode, and an electrical filter, in accordance with example embodiments;

FIG. 3 illustrates a diagram of a third example, non-limiting, on-chip filtering system that comprises a quantum device having a qubit device, an electrode, and an electrical filter, in accordance with example embodiments;

FIG. 4 illustrates an on-chip filtering system for preventing qubit energy loss, in accordance with example embodiments;

FIGS. 5-7 illustrate flow diagrams for example, non-limiting methods to facilitate on-chip filtering to prevent qubit energy loss, in accordance with example embodiments;

FIG. 8 illustrates the location of electrodes for a first example qubit configuration (top-view), in accordance with example embodiments;

FIG. 9 illustrates the location of electrodes for the first example qubit configuration (side-view), in accordance with example embodiments;

FIG. 10 illustrates the location of electrodes for a second example qubit configuration (side-view), in accordance with example embodiments;

FIG. 11 illustrates an example layout of electrodes, in accordance with an example embodiment;

FIG. 12A is a flowchart for an example method for mitigating an effect of TLSs on a qubit, in accordance with example embodiments;

FIG. 12B is a flowchart for an example method for mitigating an effect of TLSs on a tunable qubit, in accordance with example embodiments;

FIG. 13 depicts a computing environment according to an embodiment of the present invention; and

FIG. 14 is a flow diagram of a design process used in semiconductor design, manufacture, and/or test.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that, in general terms, an exemplary method, according to an aspect of the invention, includes the operations of performing an N-dimensional scan of a set of bias voltages, each bias voltage defining a voltage of a corresponding electrode 220 of a set of electrodes 220, the electrodes 220 being proximate to a given qubit 210; determining a sensitivity of a performance of the given qubit 210 to an electronic field generated by each of the electrodes 220; extrapolating a probable location of at least one two-level system (TLS) 284 based on the determined sensitivities; and mitigating an effect of the two-level system (TLS) 284 on the given qubit 210 based on the extrapolated location. The technical benefits include improvements to the T1 relaxation rate, which in turn improves qubit error rates and improves the overall performance of the qubit computer and a reduction in downtime of the qubit processor. Other technical benefits include:

improved understanding of the physical location of TLSs (more fine-grained resolution regarding the physical location);
improved gate performance and longer coherence times for qubit processors due to TLS avoidance and mitigation;
use of relatively small electrodes that are configured near each qubit of a quantum computer as a result of defining and patterning the electrodes using a lithography and etch process;
use of multiple electrodes to vary TLS behavior for improved TLS avoidance;
a reduction in a count of TLSs, a relocation of TLSs to locations that reduce the negative effects of the TLS on qubit performance, a shift in a resonant frequency of one or more defects to reduce the impact of the TLSs on the qubit device or any combination of the foregoing; and
improved coherence times due to better TLS avoidance and mitigation.

In one example embodiment, the performing of the N-dimensional scan of the set of bias voltages, the determining of the sensitivity of the performance of the given qubit 210, and the extrapolating of the probable location of the at least one two-level system (TLS) 284 based on the determined sensitivities are repeated to generate a statistical distribution of locations of the at least one two-level system (TLS) 284. The technical benefits include further improvements to the T1 relaxation rate.

In one example embodiment, the mitigating of the effect of the two-level system (TLS) 284 further comprises adjusting a manufacturing process, manufacturing a new qubit 210 and repeating the performing of the N-dimensional scan of the set of bias voltages, the determining the sensitivity of the performance of the given qubit 210, and the extrapolating of the probable location of the at least one two-level system (TLS) 284. The technical benefits include improvements to the qubit fabrication techniques, which further improves the T1 relaxation rate.

In one example embodiment, the adjusting of the manufacturing process further comprises adjusting a reactive ionic etching process. The technical benefits include achieving the advantages as discussed above with a convenient way of doing the manufacturing process.

In one example embodiment, the adjusting of the reactive ionic etching process further comprises one or more of etching for a longer time period and using an etchant that leaves less residue. The technical benefits include achieving the advantages as discussed above with a convenient way of doing the manufacturing process.

In one example embodiment, the mitigating of the effect of the two-level system (TLS) 284 further comprises retuning a frequency of the two-level system 284 away from a frequency of the given qubit 210 by adjusting one or more voltages of the set of bias voltages. The technical benefits include achieving the advantages as discussed above with a convenient way of mitigating the TLS effect.

In one example embodiment, the mitigating of the effect of the two-level system (TLS) 284 further comprises reducing a count of two-level systems 284 proximate the given qubit 210 by adjusting one or more of the voltages of the set of bias voltages. The technical benefits include achieving the advantages as discussed above with a convenient way of mitigating the TLS effect.

In one aspect, a structure comprises a substrate 224; a superconducting qubit 210 on the substrate 224; a plurality of electrodes 220 terminating near different positions of the qubit 210; a plurality of voltage sources, where each voltage source is connected to a corresponding one of the electrodes 220; and a controller 1104 configured to perform an N-dimensional scan on a set of bias voltages, each bias voltage defining a voltage of a corresponding electrode of the plurality of electrodes 220; determine a sensitivity of a performance of the qubit 210 to an electronic field generated by each of the electrodes 220; and extrapolate a location of at least one two-level system (TLS) based on the determined sensitivities. Technical benefits include the use of multiple electrodes to vary TLS behavior for improved TLS avoidance; and improved coherence times due to better TLS avoidance and mitigation.

In one example embodiment, the plurality of electrodes 220 terminating near different positions of the qubit 210 comprise electrodes 220 located on the interposer chip substrate 254. Technical benefits include improved signal routing for some device configurations.

In one example embodiment, the plurality of electrodes 220 terminating near different positions of the qubit 210 include electrodes 220 located on a back side of the substrate 224. Technical benefits include improved signal routing for some device configurations and improved tunability due to the higher dielectric constant of the substrate.

In one example embodiment, the plurality of electrodes 220 terminating near different positions of the qubit 210 include electrodes 220 located on a front side of the substrate 224. Technical benefits include improved signal routing for some device configurations.

In one example embodiment, an effect of the two-level system (TLS) 284 on the given qubit 210 is mitigated based on the extrapolated location. The technical benefits include achieving the advantages as discussed above with a convenient way of mitigating the TLS effect.

In one example embodiment, the controller 1104 is further configured to repeat the performing of the N-dimensional scan of the set of bias voltages, the determining of the sensitivity of the performance of the given qubit 210, and the extrapolating of the probable location of the at least one two-level system (TLS) 284 based on the determined sensitivities, to generate a statistical distribution of locations of the at least one two-level system (TLS) 284. The technical benefits include further improvements to the T1 relaxation rate.

In one example embodiment, the controller 1104 is further configured to mitigate an effect of the two-level system (TLS) 284 on the given qubit 210 based on the extrapolated location. The technical benefits include achieving the advantages as discussed above with a convenient way of mitigating the TLS effect.

In one example embodiment, the mitigating of the effect of the two-level system (TLS) 284 further includes retuning a frequency of the two-level system 284 away from a frequency of the given qubit 210 by adjusting one or more voltages of the set of bias voltages. The technical benefits include achieving the advantages as discussed above with a convenient way of mitigating the TLS effect.

In one example embodiment, the mitigating of the effect of the two-level system (TLS) 284 further includes reducing a count of two-level systems 284 proximate the given qubit 210 by adjusting one or more of the voltages of the set of bias voltages. The technical benefits include achieving the advantages as discussed above with a convenient way of mitigating the TLS effect.

In one example embodiment, the mitigating of the effect of the two-level system (TLS) 284 further includes retuning a frequency of the two-level system 284 away from a frequency of the given qubit 210 and reducing a count of two-level systems 284 proximate the given qubit 210 by adjusting one or more voltages of the set of bias voltages. The technical benefits include achieving the advantages as discussed above with a convenient way of mitigating the TLS effect.

In one aspect, a computer program product includes one or more tangible computer-readable storage media and program instructions stored on at least one of the one or more tangible computer-readable storage media, the program instructions executable by a processor, the program instructions including performing an N-dimensional scan of a set of bias voltages, each bias voltage defining a voltage of a corresponding electrode 220 of a set of electrodes 220, the electrodes 220 being proximate to a given qubit 210; determining a sensitivity of a performance of the given qubit 210 to an electronic field generated by each of the electrodes 220; extrapolating a probable location of at least one two-level system (TLS) 284 based on the determined sensitivities; and mitigating an effect of the two-level system (TLS) 284 on the given qubit 210 based on the extrapolated location. The technical benefits include improvements to the T1 relaxation rate, which in turn improves qubit error rates and improves the overall performance of the qubit computer and a reduction in the downtime of the qubit processor.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
improved understanding of the physical location of TLSs (more fine-grained resolution regarding the physical location);
improved gate performance and longer coherence times for qubit processors due to TLS avoidance and mitigation;
use of relatively small electrodes that are configured near each qubit of a quantum computer as a result of defining and patterning the electrodes using a lithography and etch process;
use of multiple electrodes to vary TLS behavior for improved TLS avoidance;
a reduction in a count of TLSs, a relocation of TLSs to locations that reduce the negative effects of the TLS on qubit performance, a shift in a resonant frequency of one or more defects to reduce the impact of the TLSs on the qubit device or any combination of the foregoing; and
improved coherence times due to better TLS avoidance and mitigation.

As used herein, a quantum circuit can be a set of operations, such as gates, performed on a set of real-world physical qubits with the purpose of obtaining one or more qubit measurements. A quantum processor can comprise the one or more real-world physical qubits.

Qubit states can only exist (or can only be coherent) for a limited amount of time. Thus, an objective of operation of a quantum logic circuit (including one or more qubits) is to maximize the coherence time of the employed qubits. Time spent to operate the quantum logic circuit can undesirably reduce the available time of operation on one or more qubits. This can be due to the available coherence time of the one or more qubits prior to decoherence of the one or more qubits. For example, a qubit state can be lost in less than 100 to 200 microseconds in one or more cases.

Operation of the quantum circuit can be facilitated by, for example, a waveform generator, to produce one or more physical pulses and/or other waveforms, signals and/or frequencies to alter one or more states of one or more of the physical qubits. The altered states can be measured, thus allowing for one or more computations to be performed regarding the qubits and/or the respective altered states.

Operations on qubits generally can introduce some error, such as some level of decoherence and/or some level of quantum noise, further affecting qubit availability. Quantum noise can refer to noise attributable to the discrete and/or probabilistic natures of quantum interactions.

A T1 (energy relaxation time) of a qubit can fluctuate in time. One source of the fluctuations can be the noise at the qubit frequency that varies in time. One type of such quantum noise can be due to defects called two level systems (TLS). TLSs are quantum mechanical defects that can exist in amorphous materials such as glasses or disordered solids. In such amorphous materials, the atoms or molecules are not arranged in a periodic crystal structure but are instead arranged randomly. Such random disorder creates a distribution of potential energy minima and maxima that TLSs can occupy.

Additionally, the density of TLSs in a material depends on its preparation and history. For instance, the density of TLSs in glasses can be reduced by annealing the glass at high temperatures. However, the annealing process is not always effective and can also create new TLSs. The density of TLSs can also vary depending on the cooling rate and the pressure at which the material was formed.

Further, TLSs can affect the performance of quantum circuits by introducing fluctuations or local variations in the energy landscape, leading to errors in quantum gate operations. These variations can trap charge carriers, for example, leading to fluctuations in the energy landscape that affect the performance of quantum circuits. The TLS errors can be characterized by the T1, which measures the rate at which quantum information is lost due to relaxation to the ground state.

TLSs can cause T1 relaxation times to be shorter than expected, leading to a decrease in the coherence time of quantum systems. This decrease in coherence time can limit the ability to perform long quantum algorithms and increase the error rate of quantum gate operations.

A two-level system has a transition energy (or corresponding frequency). When a TLS is resonant with the qubit frequency, the rate of energy relaxation can increase, leading to shorter T 1. TLS frequencies can change as a function of time due to spontaneous changes in the local electric field environment of the TLS. Such changes in the local electric field environment can cause an excellent qubit to suddenly become a poorly functioning qubit (e.g., low T1 times). With examples, an excellent qubit with a T1 time of 500 microseconds can suddenly become a poorly functioning qubit with a T1 time of less than 50 microseconds. With further examples, high performing superconducting qubits can have T1 times greater than 100 microseconds where Purcell loss can affect qubit performance.

A two-level system (TLS), among other noise causes, can comprise a source of noise that can cause deterioration of coherence parameters (e.g., shorter T1) of one or more qubits of a quantum logic circuit. TLSs are believed to be able to coherently or incoherently couple to the qubit, leading to either faster energy relaxation times or rate of energy decay (e.g., shorter Tls corresponding to an exponential l/e decay time) as well as faster phase decoherence (e.g., T2). That is, the noise can couple to a low-energy thermal fluctuator, for example, which can randomly change the TLS energy resonance (or the equivalent frequency of the TLS resonance). A TLS can spectrally diffuse into and out of resonance with the qubit frequency when the TLS is in the vicinity of a qubit frequency. This is a source of T1 fluctuation.

The qubit frequency is the resonance frequency of a qubit energy transition between two states such as, but not limited to, the ground and first excited states of the qubit. The vicinity of a qubit frequency is a frequency range which in some embodiments can range from about 10 megahertz (MHz) below the qubit frequency to about 10 MHz above the qubit frequency. In other embodiments, the vicinity of a qubit frequency can range from about 100 MHz below the qubit frequency to about 100 MHz above the qubit frequency. In still other embodiments, the vicinity of a qubit frequency can range from about 1 gigahertz (GHz) below the qubit frequency to about 1 GHz above the qubit frequency. Without being limited to theory, it is believed that such two-level systems can be caused by atomic scale defects in surface oxides on the metals and/or on the substrate material of a physical real-world qubit and can be electromagnetically active. Indeed, a qubit, such as a transmon, itself is a resonator with an electromagnetic excitation, and thus a qubit excitation can couple with a two-level system (TLS) and can cause performance issues for a quantum logic circuit, such as, but not limited to, deterioration of qubit parameters, such as qubit gate error rate.

Due to the presence of two-level systems in/at the quantum system and/or due to maintenance and/or diagnostics to be performed relative to coherence times of a particular qubit, one or more qubits, such as superconducting qubits, can be unavailable and/or not recommended for use with the quantum logic circuit, even if desired for use. Furthermore, absent understanding of such two-level systems and their associated fluctuations relative to the frequency domain of one or more qubits of a quantum system, coherence of the qubit can be affected. Loss of coherence can cause failure of execution of a quantum circuit.

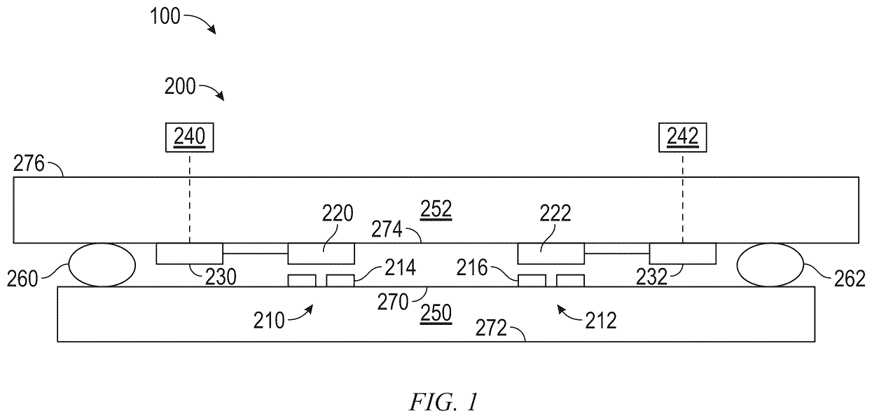

Turning first generally to FIG. 1, one or more embodiments described herein can include one or more devices, systems and/or apparatuses that can facilitate on-chip filtering to prevent qubit energy loss due to TLS defects. For example, FIG. 1 illustrates a diagram of an example, non-limiting, on-chip filtering system 100 that comprises a quantum device 200 having a qubit device 210, an electrode 220, and an electrical filter 230. The non-limiting, on-chip filtering system 100 to prevent qubit energy loss can additionally include a voltage source 240 connected to the electrode 220 via the electrical filter 230. The qubit device 210 can be fabricated on a substrate 250 and the electrode 220 can be disposed in proximity (e.g., a distance in which a target qubit can be adjusted without substantially impacting an untargeted qubit) to the qubit device 210. Further, the voltage source 240 can supply voltage to the electrode 220 to shift a resonant frequency of one or more defects to reduce TLS impact on the qubit device 210.

With embodiments, such as generally illustrated in FIG. 1, the non-limiting, on-chip filtering system 100 to prevent qubit energy loss can apply an electric field via the electrode 220 to recover and/or improve performance of the qubit device 210 (e.g., qubit T1 or qubit gate error rate). TLSs can include resonant frequencies which can coincide with the frequency of the qubit (e.g., a transmon qubit 214 of the qubit device 210). Further, TLS frequencies can wander/vary in time, which can cause rapid reductions in qubit device 210 performance. Such performance can be recovered and/or improved by applying an electric field via the electrode 220. With examples, the electrode 220 can be disposed over (e.g., in the vertical direction, or in at least one direction) the qubit device 210. Further, the electrode 220 can provide a pathway for qubit energy to escape, which can be mitigated/blocked by including an electrical filter 230 (e.g., that additionally blocks outside energy from entering the qubit device 210). However, placing an electrode (e.g., the electrode 220) in proximity to transmon qubit 214 may result in energy leakage, such as Purcell loss, from the qubit.

In examples, the electrode 220 can be one or more of a variety of components that can generate/produce an electric field proximate a qubit device 210 to effectively tune the TLS defect frequency away from the qubit device 210 frequency. In one example embodiment, the electrode 220 can be one or more loops of one or more wires, or one or more lines, whereby a common voltage can be applied to tune the frequency of the TLS defects, and such loops, wires, or lines may additionally be used in flux tuning of quantum components. In some embodiments, the electrode 220 can be a thin film of superconducting metal that is disposed in close proximity to the qubit device 210. For example and without limitation, the electrode 220 can be disposed apart from the qubit device 210 by about 50 micrometers. In example embodiments, with an increase in the distance between the electrode 220 and the qubit device 210, the voltage can be respectively increased by the voltage source 240 to compensate for any decrease in the electric field generated by the electric voltage.

In example embodiments, the electrical filter 230 can provide one or more of a variety of functions for the qubit device 210 and/or the on-chip filtering system 100. The electrical filter 230 can reflect qubit energy (e.g., energy lost through Purcell loss) back into the qubit device 210, and the electrical filter 230 can block outside energy/noise from entering and interfering with performance of the qubit device 210. Additionally, by placing the electrical filter 230 near (e.g., within a suitable distance to mitigate loss, such as ¼ of the qubit device 210) the electrode 220, energy loss that occurs during signal propagation can be limited. In this way, performance of the qubit device 210 can be enhanced/improved by including an electrode 220 and an electrical filter 230 coupled with a voltage source 240 to provide a controlled electric field, thereby controlling the frequency of one or more TLSs of the qubit device 210 and blocking external interferences and energy loss from the transmon qubit 214 itself. TLS defects include two energy levels, where the difference in energy can determine the characteristic resonant frequency of the TLS. The TLS frequency can depend on the atomic configuration of the qubit materials and the presence of an electric field. TLS defects include an associated electric dipole moment that can allow for frequency tuning via an applied electric field. The electrode 220 can generate an electrical field via the voltage source 240 such that the frequency of the TLS defect can be tuned (e.g., tuned away from the qubit device 210 frequency).

As illustrated in FIG. 1, the non-limiting, on-chip filtering system 100 to prevent qubit energy loss can include a first substrate 250 and a second substrate 252. The first substrate 250 can be disposed substantially parallel to the second substrate 252. The first substrate 250 can be one or more of a variety of qubit chips and can include the qubit device 210. Further, the qubit device 210 can be disposed on the first substrate 250. The first substrate 250 can include a first surface 270 and a second surface 272, where the first surface 270 can be opposite the second surface 272. The qubit device 210 can be disposed on the first surface 270 of the first substrate 250. The electrode 220 and the electrical filter 230 can be disposed on the second substrate 252 (see, e.g., FIG. 1). Further, the second substrate 252 can include a third surface 274 opposite a fourth surface 276. The second substrate 252 can be one or more of a variety of interposer chips; and the second substrate 252 can include ancillary circuitry for the on-chip filtering system 100 or for a variety of other connected systems.

As illustrated in FIG. 1, the on-chip filtering system 100 to prevent qubit energy loss can include an additional qubit device 212, an additional electrode 222, an additional electrical filter 232, and an additional voltage source 242. With example embodiments, any number of qubit devices 210 can be included on the first substrate 250 and/or the second substrate 252.

In example embodiments, the qubit device 210 and the additional qubit device 212 can include a transmon qubit 214 and an additional transmon qubit 216, respectively. The transmon qubit 214 and the additional transmon qubit 216 can be one or more of a variety of qubits. For example and without limitation, the transmon qubit 214 and the additional transmon qubit 216 can be flux-tunable qubits and/or phase qubits. The electrical filter 230 and the additional electrical filter 232 can include filters that can be tuned to reflect signals at a frequency of a transmon qubit 214 and the additional transmon qubit 216 (e.g., the qubit device 210 and the additional qubit device 212).

With example embodiments, such as generally illustrated in FIG. 1, the non-limiting on-chip filtering system can include the voltage source 240 and the additional voltage source 242 coupled with the electrical filter 230 and the additional electrical filter 232, respectively. The voltage source 240 and the additional voltage source 242 can supply power/voltage to the electrode 220 and the additional electrode 222, via the electrical filter 230 and the additional electrical filter 232, respectively. Supplying voltage to the electrode 220 and the additional electrode 222 can shift the resonant frequency of one or more defects of the non-limiting, on-chip filtering system 100 to reduce TLS impact (e.g., interference and/or noise) on the qubit device 210 and the additional qubit device 212. With example embodiments, the voltage source 240 and the additional voltage source 242 can supply a variety of voltages ranging from about-10V to about 10V (e.g., in small steps of about 10 mV). Additionally, the electrical filter 230 and the additional electrical filter 232 can reflect signals at the frequency of the qubit device 210 (e.g., the transmon qubit 214) and the additional qubit device 212 (e.g., the additional transmon qubit 216) such that outside noise originating from an environment exterior to the on-chip filtering system 100 does not affect performance of the transmon qubit 214 or the additional transmon qubit 216.

In example embodiments, the first substrate 250 can be a qubit chip, whereby the first substrate 250 can include the qubit device 210 and the additional qubit device 212. The second substrate 252 can be an interposer chip that can include various circuitry for supporting/controlling the qubit device 210 and the additional qubit device 212. Further, as indicated in FIG. 1, the first substrate 250 (e.g., the qubit chip) can be bump-bonded with the second substrate 252 (e.g., the interposer chip) via one or more bump-bonds 260, 262. The first substrate 250 can be bump-bonded with the second substrate 252 such that the first surface 270 of the first substrate 250 is proximate the third surface 274 of the second substrate 252. Further, the electrode 220 and the additional electrode 222 disposed on the second substrate 252 can be in close proximity to the qubit device 210 and the additional qubit device 212 disposed on the first substrate 250. With example embodiments, the electrode 220 and the additional electrode 222 can be aligned (e.g., at least partially, or fully, overlapping) in at least one direction (e.g., vertically) with the qubit device 210 and the additional qubit device 212. The electrode 220 and the additional electrode 222 can be aligned in a first direction (e.g., a horizontal direction along the second substrate 252) with the electrical filter 230 and the additional electrical filter 232; and the electrode 220 and the additional electrode 222 can be aligned in a second direction (e.g., a vertical direction perpendicular to the first direction) with the transmon qubit 214 and the additional transmon qubit 216.

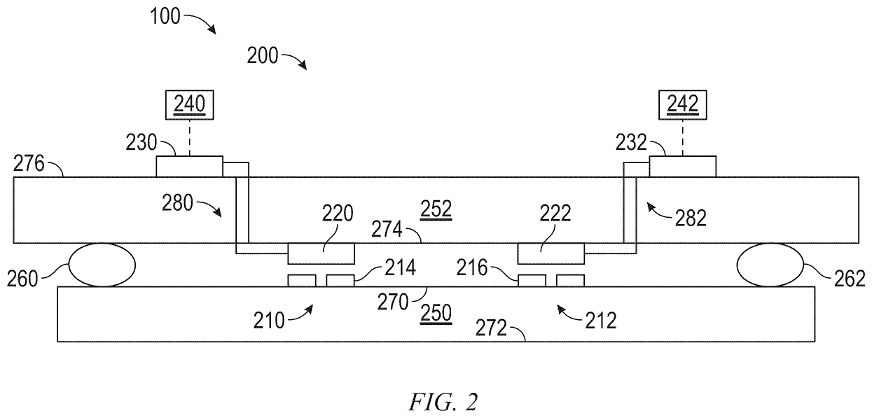

Turning next to FIG. 2, the non-limiting, on-chip filtering system 100 to prevent qubit energy loss can include one or more of a variety of configurations. For example and without limitation, the electrical filter 230 and the additional electrical filter 232 can be disposed on a different surface than the electrodes 220, 222 and the qubit devices 210, 212. The electrical filter 230 and the additional electrical filter 232 can be disposed on the fourth surface 276 of the second substrate 252. The electrical filter 230 and the additional electrical filter 232 can be disposed on an opposite surface with respect to the electrode 220 and the additional electrode 222; further, the electrical filter 230 and the additional electrical filter 232 can be disposed on opposite sides of the second substrate 252.

With example embodiments, the non-limiting, on-chip filtering system 100 to prevent qubit energy loss can include one or more thru substrate vias (TSVs) that can couple the electrical filter 230 to the electrode 220 and can couple the additional electrical filter 232 to the additional electrode 222, such that voltage can be applied through the second substrate 252. In example embodiments, the electrical filter 230 and the additional electrical filter 232 can be disposed on an opposite side with respect to the electrode 220 and the additional electrode 222 to preserve wiring space and/or minimize interferences with the on-chip filtering system 100. The on-chip filtering system 100 can include a TSV 280 and an additional TSV 282.

In example embodiments, such as generally illustrated in FIG. 2, the TSV 280 can electrically couple the voltage source 240 and the electrical filter 230 with the electrode 220 such that the voltage source 240 can supply a voltage to the electrode 220 to create an electric field within the vicinity (e.g., proximate) of the qubit device 210 to change the frequencies of the TLSs such as to not interfere with qubit device 210 performance (e.g., qubit T1). The additional TSV 282 can electrically couple the additional voltage source 242 and the additional electrical filter 232 with the additional electrode 222 such that the additional voltage source 242 can supply a voltage to the additional electrode 222 to create an electric field within the vicinity (e.g., proximate) of the additional qubit device 212 to change the frequencies of the TLSs such as to not interfere with additional qubit device 212 performance (e.g., qubit T1).

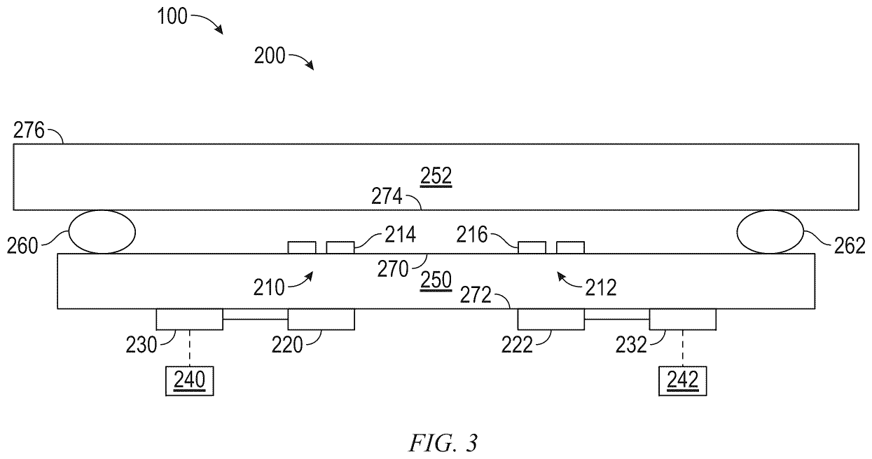

Turning to FIG. 3, the non-limiting, on-chip filtering system 100 to prevent qubit energy loss can include a configuration where the qubit device 210, the electrode 220, and the electrical filter 230 can be disposed on the same substrate (e.g., the first substrate 250). Alternatively, in one or more various embodiments, the electrical filter 230 can be disposed on the second substrate 252. The qubit device 210 can be disposed on the first surface 270 of the first substrate 250; and the electrode 220 and the electrical filter 230 can be disposed on the second surface 272 of the first substrate 250. In a similar manner, the additional qubit device 212, the additional electrode 222, and the additional electrical filter 232 can be disposed on the same substrate (e.g., the first substrate 250). Alternatively, in one or more various embodiments, the additional electrical filter 232 can be disposed on the second substrate 252. The additional qubit device 212 can be disposed on the first surface 270 of the first substrate 250; and the additional electrode 222 and the electrical filter 232 can be disposed on the second surface 272 of the first substrate 250.

With example embodiments, such as generally illustrated in FIGS. 1-3, the electrode 220 and the additional electrode 222 can be disposed less than about a quarter of a wavelength λ/4 away from the electrical filter 230 and the additional electrical filter 232, respectively. The wavelength λ can be determined by the frequency f of the qubit and the propagation velocity v of signals in the wiring according to λ=v/f. In example embodiments, a quarter of a wavelength can be less than about 1 centimeter.

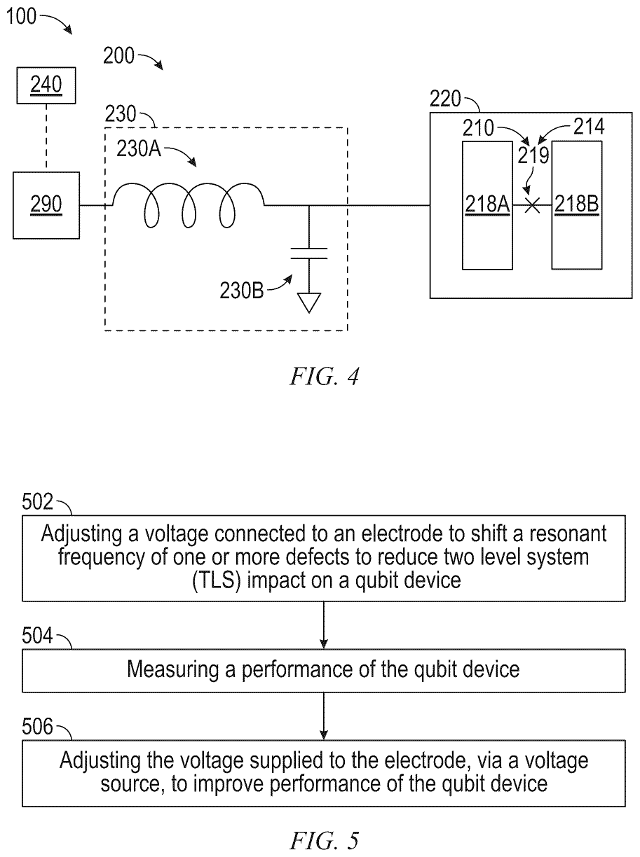

In example embodiments, such as generally illustrated in FIG. 4, the on-chip filtering system 100 to prevent qubit energy loss can include an electrical filter 230. The electrical filter 230 can include one or more of a variety of components and/or types. For example and without limitation, the electrical filter 230 can be any type/arrangement of filter elements to result in a low-pass response with a cut-off frequency of about 1.5 GHz to about 2.0 GHz. That is, the frequency of the qubit device 210 (e.g., the transmon qubit 214) can be about 5 GHZ, and the electrical filter 230 can be connected/selected to reject and reflect signals with frequencies higher than the filter cut-off frequencies, including the frequency of the qubit device 210.

With example embodiments, the electrical filter 230 can be any variety of low loss filter and can be constructed from superconducting elements. Further, the electrical filter 230 can be a low pass filter, a band reject filter (e.g., consisting of an open-ended quarter-wave stub fabricated using coplanar waveguide circuitry), and a combination of low pass and band reject filters (e.g., for a more complete rejection of energy leakage from the qubit and to protect the introduction of noise at both the qubit frequency and the resonator readout frequency).

In example embodiments, the qubit device 210 can be a transmon qubit 214 and can further comprise a first capacitor plate 218A, a second capacitor plate 218B, and a Josephson junction 219, as shown in FIG. 4. The Josephson junction 219 can bridge the first capacitor plate 218A with the second capacitor plate 218B.

As illustrated in FIG. 4, the electrode 220 can be coupled (e.g., electrically) with the electrical filter 230 which can include an inductor 230A and a capacitor 230B. The electrical filter 230 can reject frequencies that are similar/near to the frequency of the qubit device 210 (e.g., frequencies greater than about 1.5 GHZ). The electrical filter 230 can effectively prevent/limit energy of the qubit device 210 from leaving and can prevent noise from entering and disturbing the qubit device 210. With example embodiments, the inductor 230A and the capacitor 230B can be one or more of a variety of inductors or capacitors used with quantum devices. For example, the inductor 230A can be a spiral inductor and the capacitor 230B can be implemented as a planar interdigitated capacitor. The filter components can be made from superconducting materials (e.g., niobium, aluminum, tantalum, titanium nitride, and the like) in order to avoid electrical dissipation. Additionally, the input of the electrical filter 230 can be coupled to external circuitry 290, which can include circuit boards, coaxial cables, and additional filters for the on-chip filtering system 100. The external circuitry 290 can be coupled to and/or can include the voltage source 240 that provides a voltage to the electrode 220 for tuning the frequencies of the TLSs.

In example embodiments, the voltage source 240 can supply a voltage that can range from about −10V to about 10V to be applied to the electrode 220. The electrode 220 (e.g., the voltage source 240) can generate an electric field proximate the qubit device 210 that can change the frequencies of the TLSs such that an optimal voltage (Vₒₚₜ) can be found to improve performance of the qubit device 210. The non-limiting, on-chip filtering system 100 to prevent qubit energy loss can adjust the voltage supplied to the electrode 220, via the voltage source 240, to improve performance of the qubit device 210 (e.g., to improve T1 of the qubit device 210) as TLS defect frequencies change/vary during operation of the non-limiting, on-chip filtering system 100 and the qubit device 210. The voltage source 240 can provide a sweep of voltages such that the qubit device 210 produces maximum T1 values (e.g., where qubit coherence time is improved) and can maintain performance of the qubit device 210 above a minimum performance value (e.g., T1ₛₑₜₚₒᵢₙₜ). Alternatively, the voltage supplied by the voltage source 240 can be chosen to minimize the gate error rate of quantum gate operations.

FIG. 5 illustrates a flow diagram of an example, non-limiting method to facilitate on-chip filtering to prevent qubit energy loss in accordance with one or more embodiments described herein. Performance of the on-chip filtering system 100 can be improved with respect to measurement of the qubit relaxation time T1, where a minimum acceptable T1 value (e.g., T1ₛₑₜₚₒᵢₙₜ) can be set and the non-limiting method can maintain qubit performance above the minimum acceptable T1 value. Repetitive description of like elements and/or processes employed in respective embodiments is omitted for sake of brevity.

At 502, the non-limiting method to facilitate on-chip filtering to prevent qubit energy loss comprises adjusting a voltage connected to an electrode 220 to shift a resonant frequency of one or more defects to reduce TLS impact on the qubit device 210.

At 504, the non-limiting method to facilitate on-chip filtering to prevent qubit energy loss comprises measuring a performance of the qubit device 210. In example embodiments, performance can comprise a gate error rate and/or a T1 time.

At 506, the non-limiting method to facilitate on-chip filtering to prevent qubit energy loss comprises adjusting the voltage supplied to the electrode 220, via a voltage source 240, to improve performance of the qubit device 210.

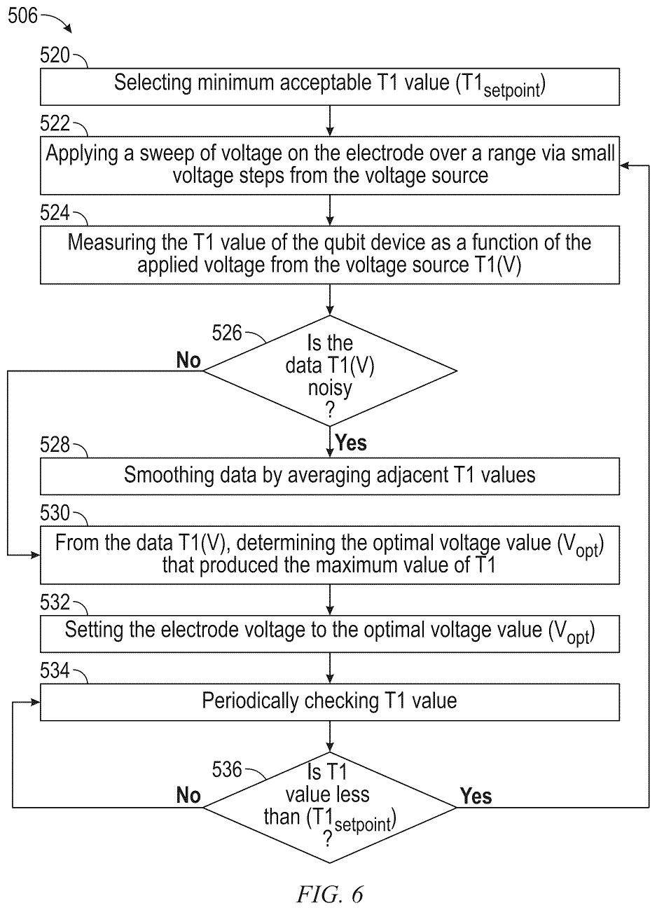

Additionally, step 506 can further be described by the continued flowchart illustrated in FIG. 6. Adjusting the voltage supplied to the electrode 220 to improve performance of the qubit device 210 can comprise one or more of a variety of steps. For example, at 520, the non-limiting method comprises selecting a minimum acceptable T1 value (e.g., T1ₛₑₜₚₒᵢₙₜ).

At 522, the non-limiting method comprises applying a sweep of voltages on the electrode 220 over a range (e.g., a range of −10 V to +10 V) via small voltage steps from the voltage source 240 (e.g., voltage steps of about 10 mV).

At 524, the non-limiting method comprises measuring the T1 value of the qubit device 210 as a function of the applied voltage from the voltage source 240 (e.g., T1 (V)).

At 526, the non-limiting method comprises determining if the data (e.g., the T1 (V)) is noisy. In response to a determination of noisy data, at 528, the non-limiting method comprises smoothing the data by averaging adjacent T1 values over the data (e.g., T1 (V)).

At 526, the non-limiting method determines the data is not noisy and proceeds to step 530 without performing step 528. Further, at 530, the non-limiting method comprises determining the optimal voltage value (Vₒₚₜ) that produced the maximum value of T1 based on the data (e.g., T1 (V)).

At 532, the non-limiting method comprises setting the voltage of the electrode 220 to the optimal voltage value (Vₒₚₜ).

At 534, the non-limiting method comprises periodically checking the T1 value. Additionally, at 536, the non-limiting method comprises determining if the T1 value is less than the minimum acceptable T1 value (e.g., T1ₛₑₜₚₒᵢₙₜ). In response to a determination that the T1 value is less than the T1ₛₑₜₚₒᵢₙₜ, the non-limiting method performs step 522 of applying a sweep of voltages to determine the optimal voltage value (Vₒₚₜ). If the T1 value is not less than the minimum acceptable T1 value, the non-limiting method continues to periodically check the T1 value to verify performance of the qubit device 210.

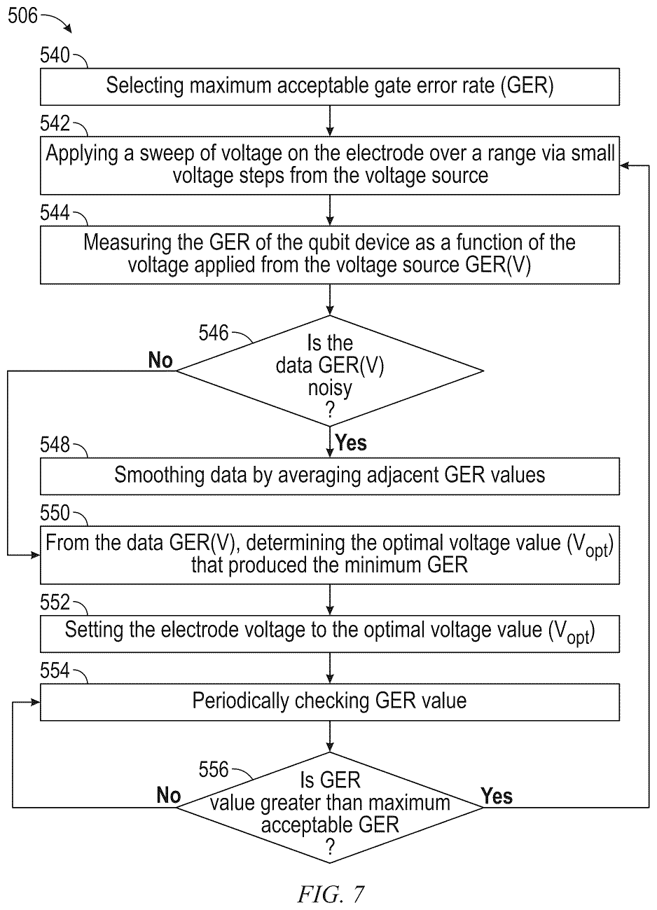

Additionally or alternatively, step 506 can further be described by the continued flowchart illustrated in FIG. 7. Adjusting the voltage supplied to the electrode 220 to improve performance of the qubit device 210 can comprise one or more of a variety of steps. For example, the variety of steps can involve evaluating a Gate Error Rate (GER) of the qubit device 210 (e.g., in contrast to evaluating performance based on T1 values). At 540, the method can comprise selecting a maximum acceptable GER of the qubit device 210.

At 542, the non-limiting method comprises applying a sweep of voltages on the electrode 220 over a range (e.g., a range of −10 V to +10 V) via small voltage steps from the voltage source 240 (e.g., voltage steps of about 10 mV).

At 544, the non-limiting method comprises measuring the GER of the qubit device 210 as a function of the applied voltage from the voltage source 240 (e.g., GER (V)).

At 546, the non-limiting method comprises determining if the data (e.g., the GER (V)) is noisy. In response to a determination of noisy data, at 548, the non-limiting method comprises smoothing the data by averaging adjacent GER values over the data (e.g., GER (V)).

At 546, the non-limiting method determines the data is not noisy and proceeds to step 550 without performing step 548. Further, at 550, the non-limiting method 500 comprises determining the optimal voltage value (V opt) that produced the minimum value of GER based on the data (e.g., GER (V)).

At 552, the non-limiting method 500 comprises setting the voltage of the electrode 220 to the optimal voltage value (Vₒₚₜ).

At 554, the non-limiting method 500 comprises periodically checking the GER value. Additionally, at 556, the non-limiting method 500 comprises determining if the GER value is less than the maximum acceptable GER value. In response to a determination that the GER value is greater than the maximum acceptable GER, the non-limiting method 500 performs step 542 of applying a sweep of voltages to determine the optimal voltage value (Vₒₚₜ). If the GER value is less than the maximum acceptable GER value, the non-limiting method 500 continues to periodically check the GER value to verify performance of the qubit device 210.

In one example embodiment, triangulation is performed using, for example, the configurations of FIGS. 1-3. As described above, the T1 time of qubits 210 is subject to time variations due to two-level-systems, defects which reside in the dielectrics which are part of and nearby the qubit devices. As the TLS degrades the coherence time of the qubit 210, and the degraded coherence time of the qubit 210, in turn, degrades the performance of the quantum processor, it is desirable to know the precise locations, coupling strengths and densities of the TLSs so they can be removed or reduced through process fabrication, the electric fields generated by the electrodes 220 and the like. This includes information about whether the TLS resides in the substrate, at the metal-air/metal-substrate/substrate-air interfaces, at parasitic junctions from the contact region formed during the Josephson junction (JJ) deposition, at the JJ metal leads, at the JJ tunneling oxide, and the like. Triangulating the exact location of these TLSs can be invaluable when developing fabrication processes and configuring the electrodes 220 to reduce the TLS density and otherwise mitigate the effects of the TLSs.

### Triangulation

FIG. 8 illustrates the location of electrodes 220 for a first example qubit configuration (top-view), in accordance with example embodiments. In one example embodiment, the electrodes 220 are located on a substrate 224 proximate a qubit 210 to assist in determining the location of a TLS 284. The electrodes 220 may be configured in a grid, as described more fully below by way of example in conjunction with FIG. 11. Bumps 216 provide spacing between the substrate 224 and an interposer chip (not shown in FIG. 8). In one example embodiment, the bumps 216 are fabricated of a suitable superconducting material. Interposer chip metal 212 carries signals to, for example, the qubit 210 and metal layer 228 is coupled to ground.

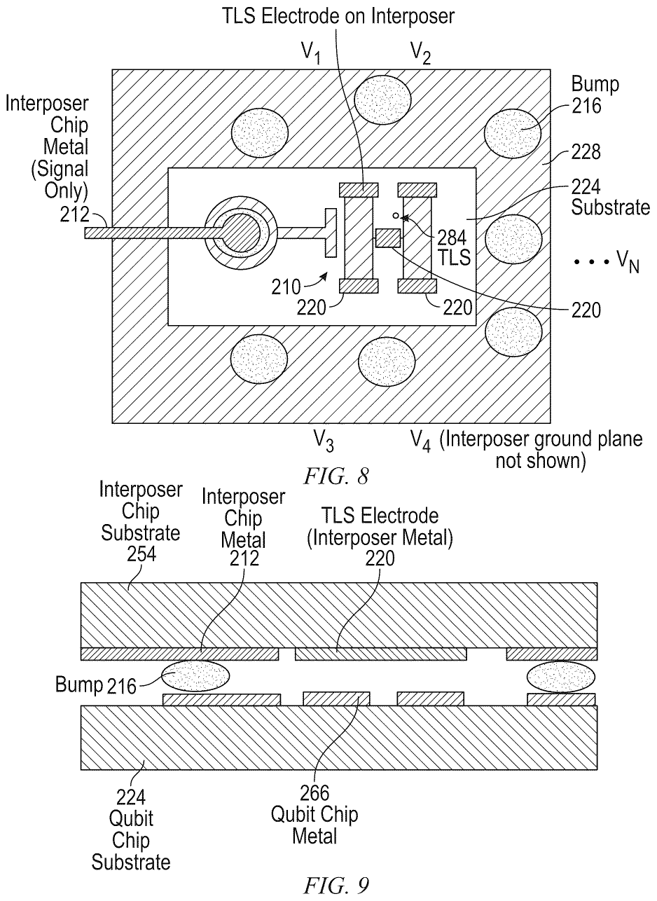

FIG. 9 illustrates the location of electrodes 220 for the first example qubit configuration (side-view), in accordance with example embodiments. In one example embodiment, the electrodes 220 are located on the substrate 224 proximate the qubit 210 (see, qubit chip metal 266). As noted above, the bumps 216 provide spacing between the substrate 224 and an interposer chip substrate 254. The interposer chip metal 212 carries signals to, for example, the qubit 210. In one example embodiment, on-chip and off-chip low-pass filters are inserted in the TLS control line to filter noise from the control signal that establishes the specified voltages on the electrodes 220.

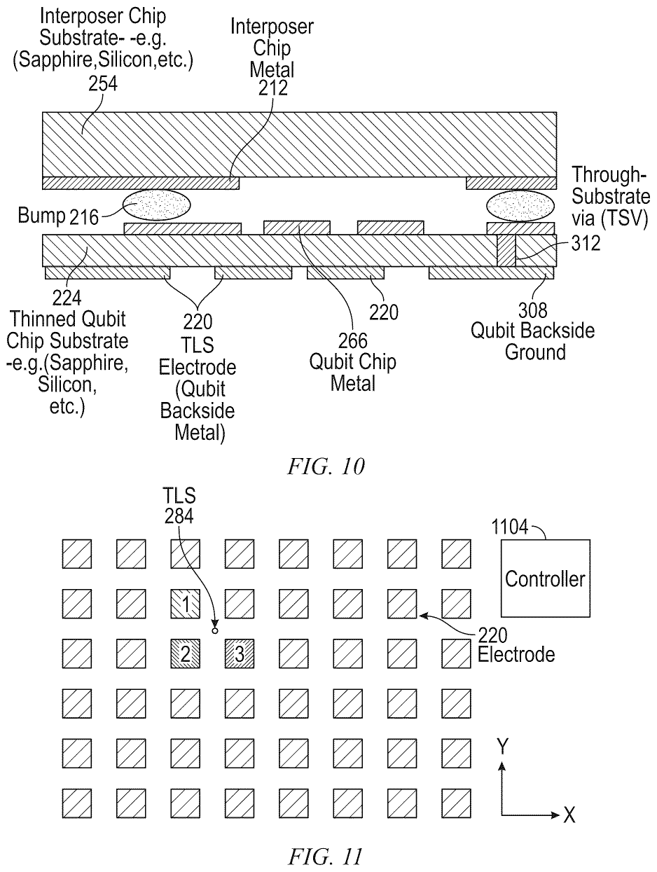

FIG. 10 illustrates the location of electrodes 220 for a second example qubit configuration (side-view), in accordance with example embodiments. In one example embodiment, the electrodes 220 are located on a backside of the substrate 224 proximate the qubit 210. (In one example embodiment, the electrodes 220 are located on a backside of the substrate 224 proximate the qubit 210, a frontside of the substrate 224 proximate the qubit 210 or both.) As noted above, the bumps 216 provide spacing between the substrate 224 and the interposer chip substrate 254. Through-substrate vias (TSVs) 312 provide connectivity to the qubit backside ground 308. In one example embodiment, the TSVs 312 carry the specified voltage to the electrodes 220.

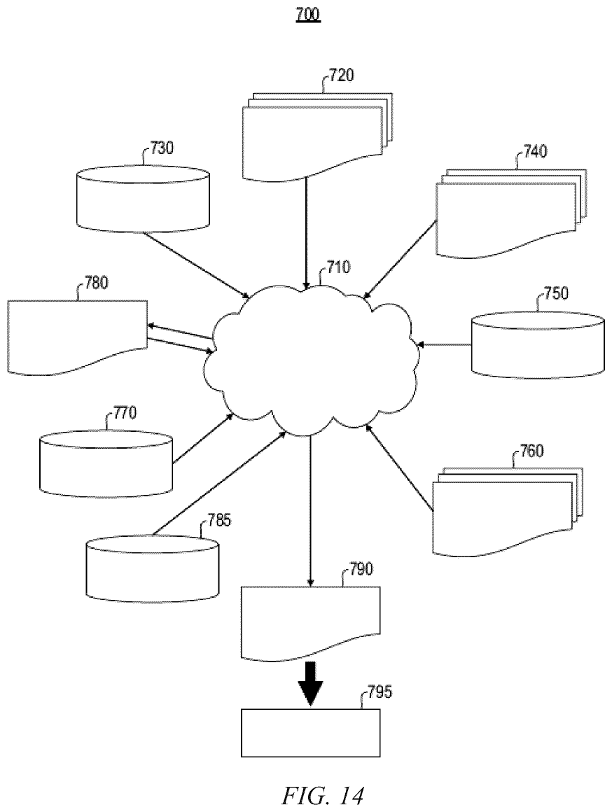

FIG. 11 illustrates an example configuration of the electrodes 220, in accordance with example embodiments. In one example embodiment, the electrodes 220 are configured in a grid pattern proximate a qubit 210 on the backside of the substrate 224, on the interposer chip substrate 254 and the like. A voltage source, controlled by controller 1104, is coupled to each of a plurality of the electrodes 220 to control an electric field generated by the electrode 220, as described more fully above. Voltage source(s) 240, 242 and connections are omitted to avoid clutter. Given the teachings herein, the skilled artisan can synthesize a digital controller to control the voltage source(s) using techniques as set forth in FIG. 14 and can connect same.

In one example embodiment, the electrodes 220 are used to tune the resonant frequencies w of defects, such as TLSs 284, by exposing the qubits 210 to electric fields E produced by the electrodes 220. The coupling strength to each electrode 220 is determined and compared to a simulation of the field distribution. A probability for a location of the TLS 284 is generated based on the comparison simulation.

The position is determined by using the qubit 210 to monitor resonant frequencies w of defects, such as TLSs 284, as voltages applied to the electrodes 220 are swept through various voltage ranges. In particular, the position of the TLS 284 is determined by comparing the response, such as the energy relaxation rate T1, to the spatial variation of the applied electric fields obtained from finite element simulations. The relative frequency shift of the TLS 284 will depend on its closeness to each electrode 220. In one example embodiment, the electric field is calculated for each combination of voltages applied to the electrodes 220; the location of the TLS 284 is then determined.

In one example embodiment, the electrodes 220 are used to tune the resonant frequency ω of a TLS defect 284 which is located at position r₀. If the resonant frequency ω of a TLS defect 284 is tuned away from the resonant frequency of the qubit 210, then the adverse effects of the TLS 284 on the qubit 210 will be reduced. It is noted that the position of the TLS 284 is not known initially; it is the goal of the triangulation procedure to determine the position r₀ of the TLS 284 on the surface of the qubit 210.

The equation for the frequency ω of an individual TLS 284 is defined as:

$$ω ( {r}_{0} ) = \sqrt{{Δ}_{0}^{2} + {( ∈ + 2 p \cdot E ( {r}_{0} ) )}^{2}} / ℏ$$

Here, E(r₀) is the electric field at the position of the TLS 284 due to voltages on the electrodes 220, p is the dipole moment of the TLS 284, and ∈ and Δ₀ are parameters that depend on the local atomic configuration and material properties of the TLS 284. It is noted that the above equation is meant to illustrate the physics and, in particular, the dependence of omega on r₀ through E(r₀). As long as ∈ and Δ₀ do not depend on voltage, ∈ and Δ₀ behave as fixed constants that cancel out in the analysis below. The qubit 210 is assumed to be of a tunable variety so that it can be used as a sensor to determine the frequency of the TLS 284, for example, by performing qubit swap spectroscopy.

If there are N electrodes 220 with a set of voltages {V₁, V₂, . . . . V_{N}} applied to the electrodes 220, the following equation can be written:

$$2 p \cdot E ( {r}_{0} ) = {α}_{1} ( {r}_{0} ) {V}_{1} + {α}_{2} ( {r}_{0} ) {V}_{2} + … + {α}_{N} ( {r}_{0} ) {V}_{N}$$

The parameters αᵢ characterize the effectiveness of each electrode 220 for tuning the frequency of the TLS 284, as described more fully below.

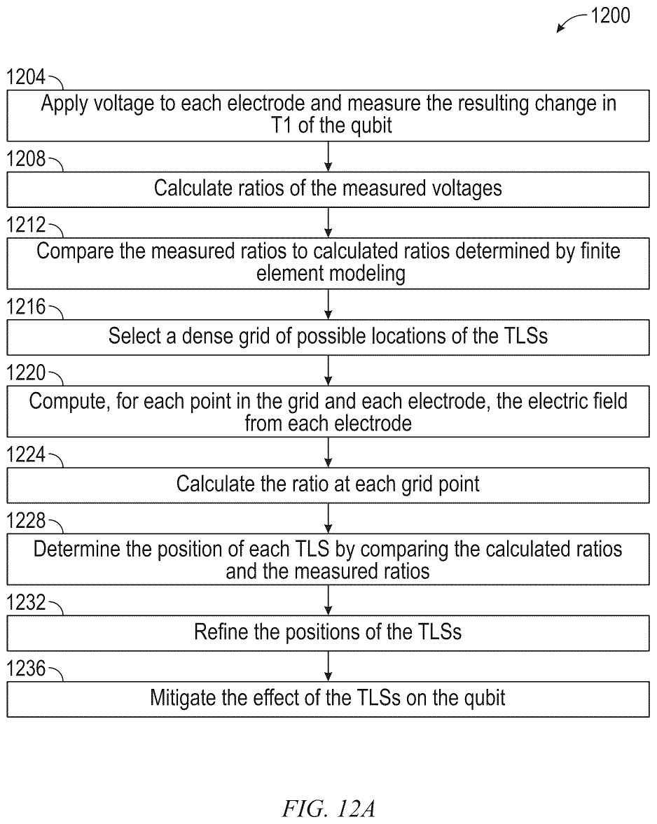

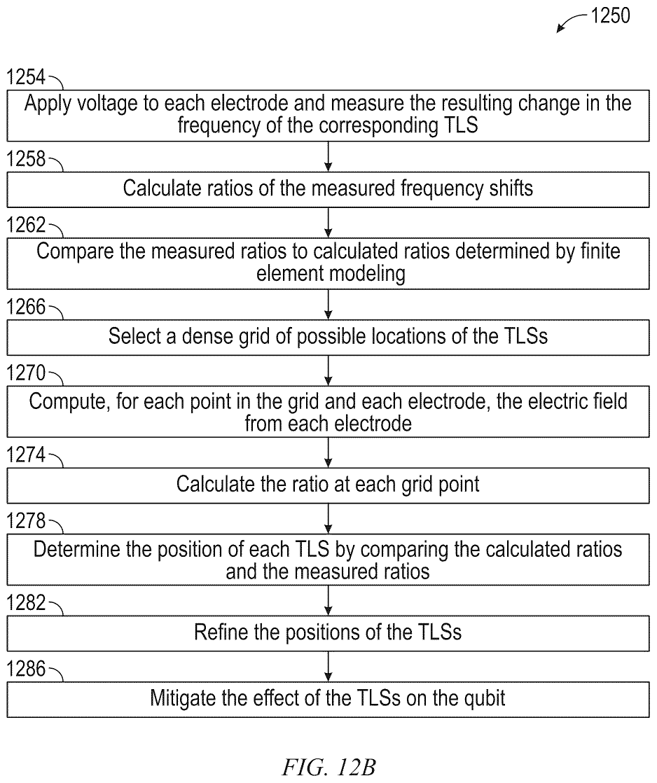

FIG. 12A is a flowchart for an example method 1200 for mitigating an effect of TLSs 284 on a qubit 210, in accordance with example embodiments. In one example embodiment, the first step in the triangulation procedure is to sequentially apply known voltages ΔVᵢ one at a time to each electrode 220 and measure the resulting change in the T1 of the qubit 210 (operation 1204). Ratios R of the measured voltages are then calculated (operation 1208):

$${R}_{ij}^{measured} ( {r}_{0} ) = \frac{Δ {ω}_{i} / {Δ V}_{i}}{\frac{\partial {ω}_{j}}{\partial {V}_{j}}} \approx \frac{\partial {ω}_{i} / \partial {V}_{i}}{\frac{\partial {ω}_{j}}{\partial {V}_{j}}} \approx \frac{{V}_{j}}{{V}_{i}} = \frac{{α}_{i} ( {r}_{0} )}{{α}_{j} ( {r}_{0} )}$$

In order to find the position r₀ of the TLS 284, the ration

$${R}_{ij}^{measured} ( {r}_{0} )$$

is compared to calculated ratios determined by finite element modeling (operation 1212). A dense grid of possible locations of the TLSs 284 is chosen (operation 1216). For each point in the grid, denoted by rₖ, the electric field from each electrode 220 is computed (operation 1220). For example, with V₁=1 volt and all other electrodes 220 assumed to be at 0 volts, the electric field at each point rₖ is calculated. This calculation is repeated for each electrode 220 and each grid point, resulting in a set of electric field values

$${E}_{i}^{calc} ( {r}_{k} ) .$$

These electric field values are related to the α parameters by:

$${α}_{i}^{calc} ( {r}_{k} ) = 2 p \cdot {E}_{i}^{calc} ( {r}_{k} ) / {V}_{i} = 2 {pE}_{i}^{calc} ( {r}_{k} ) cos {θ}_{i}$$

where θᵢ is the angle between the dipole moment and the electric field vector.

To compare to the measured results, the ratio at each grid point is then calculated (operation 1224):

$${R}_{ij}^{calc} ( {r}_{k} ) = {α}_{i}^{calc} ( {r}_{k} ) / {α}_{j}^{c a l c} ( {r}_{k} ) = {E}_{i}^{calc} ( {r}_{k} ) / {E}_{j}^{calc} ( {r}_{k} ) ,$$

where it is assumed that cos θᵢ is roughly independent of the electrode index.

To determine the position of the TLS 284, the calculated ratios are compared to the experimentally measured ratios (operation 1228). The value of rₖ that gives the closest match is the approximate location of the TLS 284. Finer determination of the position of the TLS 284 can be accomplished by interpolating between the grid points, or by refining the calculations using a finer grid (operation 1232). The effects of the TLSs 284 on the qubit 210 are mitigated, as described more fully below (operation 1236).

FIG. 12B is a flowchart for an example method 1250 for mitigating an effect of TLSs 284 on a tunable qubit 210, in accordance with example embodiments. In one example embodiment, the first step in the triangulation procedure is to sequentially apply known voltages ΔVᵢ one at a time to each electrode 220 and measure the resulting change in TLS frequency Δωᵢ (operation 1254). Ratios R of the measured frequency shifts are then tabulated (operation 1258):

$${R}_{ij}^{measured} ( {r}_{0} ) = \frac{Δ {ω}_{i} / {Δ V}_{i}}{Δ {ω}_{j} / {Δ V}_{j}} \approx \frac{\partial {ω}_{i} / \partial {V}_{i}}{\partial {ω}_{j} / \partial {V}_{j}} = \frac{{α}_{i} ( {r}_{0} )}{{α}_{j} ( {r}_{0} )}$$

In order to find the position r₀ of the TLS 284, the ration

$${R}_{ij}^{measured} ( {r}_{0} )$$

is compared to calculated ratios determined by finite element modeling (operation 1262). A dense grid of possible locations of the TLSs 284 is chosen (operation 1266). For each point in the grid, denoted by rₖ, the electric field from each electrode 220 is computed (operation 1270). For example, with V₁=1 volt and all other electrodes 220 assumed to be at 0 volts, the electric field at each point rₖ is calculated. This calculation is repeated for each electrode 220 and each grid point, resulting in a set of electric field values

$${E}_{i}^{calc} ( {r}_{k} ) .$$

These electric field values are related to the α parameters by:

$${α}_{i}^{calc} ( {r}_{k} ) = 2 p \cdot {E}_{i}^{calc} ( {r}_{k} ) / {V}_{i} = 2 {pE}_{i}^{calc} ( {r}_{k} ) cos {θ}_{i}$$

where θᵢ is the angle between the dipole moment and the electric field vector.

To compare to the measured results, the ratio at each grid point is then calculated (operation 1274):

$${R}_{ij}^{calc} ( {r}_{k} ) = {α}_{i}^{calc} ( {r}_{k} ) / {α}_{j}^{c a l c} ( {r}_{k} ) = {E}_{i}^{calc} ( {r}_{k} ) / {E}_{j}^{calc} ( {r}_{k} ) ,$$

where it is assumed that cos θᵢ is roughly independent of the electrode index.

To determine the position of the TLS 284, the calculated ratios are compared to the experimentally measured ratios (operation 1278). The value of rₖ that gives the closest match is the approximate location of the TLS 284. Finer determination of the position of the TLS 284 can be accomplished by interpolating between the grid points, or by refining the calculations using a finer grid (operation 1282). The effects of the TLSs 284 on the qubit 210 are mitigated, as described more fully below (operation 1286).

The above triangulation processes are suitable for determining fabrication properties that reduce the density of TLSs 284, relocate the TLSs 284 to a location where the adverse effects of the TLS 284 on the qubit 210 will be reduced, to tune the resonant frequency ω of the TLS defect 284 away from the resonant frequency of the qubit 210 and the like by, for example, identifying the largest density and probable locations of TLSs 284. It is noted that the bias voltage is selected on a per-chip basis, and even changes dependent on the temperature of the qubit device 210. Moreover, while the TLS resonant frequency changes over time and voltages are adjusted on, for example, an hourly or daily basis, the location of the TLS 284 is stable. In addition to the T1 parameter, the T2 parameter, two qubit randomized benchmarking, single qubit randomized benchmarking and the like may be used for conducting the triangulation process.

In one example embodiment, the manufacturing process includes chemical mechanical polishing (CMP), metal deposition and the like and the mitigation includes removing contamination and oxidation using chemical processes based on the locations of the TLSs 284 and the like. In one example embodiment, the reduced count of TLSs 284 leads to improved T1 relaxation times. In one example embodiment, improved coherence times are achieved due to better TLS avoidance and mitigation.

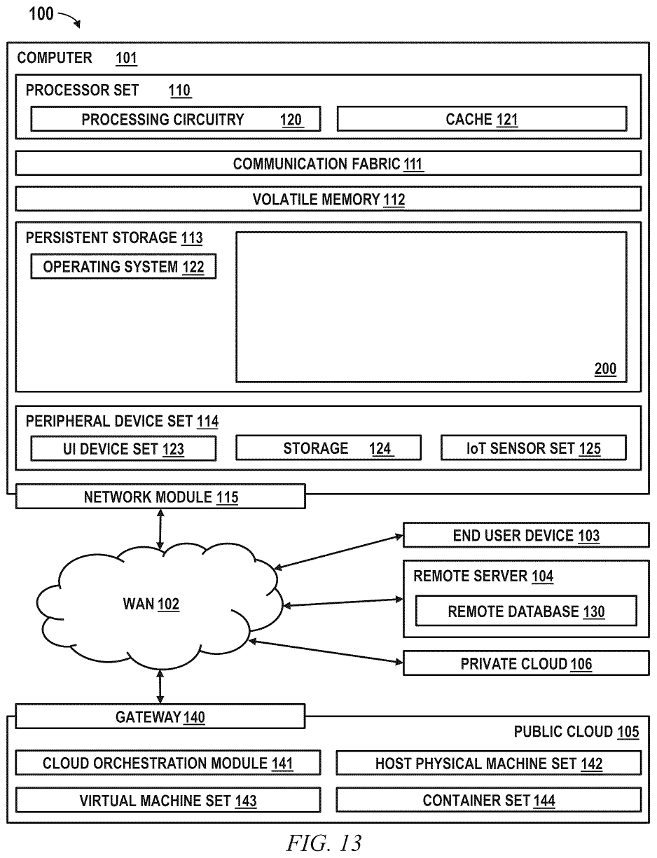

Refer now to FIG. 13. Note that the TLS triangulation and mitigation routine 200 discussed below can implement aspects of the invention and can mitigate TLS by, for example, interfacing with fabrication equipment, working with a controller 1104 to adjust voltages, and the like. The controller 1104 can be further configured to cause the system to implement any one, some, or all of the method steps disclosed herein. As noted, given the teachings herein, the skilled artisan can synthesize a digital controller to control the voltage source(s) using techniques as set forth in FIG. 14 and can connect same.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as TLS triangulation and mitigation routine 200 implementing aspects of the invention. Block 200 may also serve as a system for semiconductor design and/or control of semiconductor fabrication (see FIG. 14). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 13. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Exemplary Design Process Used in Semiconductor Design, Manufacture, and/or Test

One or more embodiments make use of computer-aided semiconductor integrated circuit design simulation, test, layout, and/or manufacture. In this regard, FIG. 14 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 5 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 790 may then proceed to a stage 795 where, for example, design structure 790: proceeds to tape-out, is released to manufacturing, is released to a mask house, is sent to another design house, is sent back to the customer, etc.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
performing an N-dimensional scan of a set of bias voltages, each bias voltage defining a voltage of a corresponding electrode of a set of electrodes, the electrodes being proximate to a given qubit;
determining a sensitivity of a performance of the given qubit to an electronic field generated by each of the electrodes;
extrapolating a probable location of at least one two-level system (TLS) based on the determined sensitivities; and
mitigating an effect of the two-level system (TLS) on the given qubit based on the extrapolated location.

2. The method of claim 1, further comprising repeating the performing of the N-dimensional scan of the set of bias voltages, the determining of the sensitivity of the performance of the given qubit, and the extrapolating of the probable location of the at least one two-level system (TLS) based on the determined sensitivities, to generate a statistical distribution of locations of the at least one two-level system (TLS).

3. The method of claim 1, wherein the mitigating of the effect of the two-level system (TLS) further comprises adjusting a manufacturing process, manufacturing a new qubit and repeating the performing of the N-dimensional scan of the set of bias voltages, the determining the sensitivity of the performance of the given qubit, and the extrapolating of the probable location of the at least one two-level system (TLS).

4. The method of claim 3, wherein the adjusting of the manufacturing process further comprises adjusting a reactive ionic etching process.

5. The method of claim 4, wherein the adjusting of the reactive ionic etching process further comprises one or more of etching for a longer time period and using an etchant that leaves less residue.

6. The method of claim 1, wherein the mitigating of the effect of the two-level system (TLS) further comprises retuning a frequency of the two-level system away from a frequency of the given qubit by adjusting one or more voltages of the set of bias voltages.

7. The method of claim 1, wherein the mitigating of the effect of the two-level system (TLS) further comprises reducing a count of two-level systems proximate the given qubit by adjusting one or more of the voltages of the set of bias voltages.

8. A structure comprising:
a substrate;
a superconducting qubit on the substrate;
a plurality of electrodes terminating near different positions of the qubit;
a plurality of voltage sources, where each voltage source is connected to a corresponding one of the electrodes; and
a controller configured to:
perform an N-dimensional scan on a set of bias voltages, each bias voltage defining a voltage of a corresponding electrode of the plurality of electrodes;
determine a sensitivity of a performance of the qubit to an electronic field generated by each of the electrodes; and
extrapolate a location of at least one two-level system (TLS) based on the determined sensitivities.

9. The structure of claim 8, further comprising an interposer chip substrate, wherein the plurality of electrodes terminating near different positions of the qubit comprise electrodes located on the interposer chip substrate.

10. The structure of claim 8, wherein the plurality of electrodes terminating near different positions of the qubit comprise electrodes located on a back side of the substrate.

11. The structure of claim 8, wherein the plurality of electrodes terminating near different positions of the qubit comprise electrodes located on a front side of the substrate.

12. The structure of claim 8, the controller further configured to repeat the performing of the N-dimensional scan of the set of bias voltages, the determining of the sensitivity of the performance of the given qubit, and the extrapolating of the probable location of the at least one two-level system (TLS) based on the determined sensitivities, to generate a statistical distribution of locations of the at least one two-level system (TLS).

13. The structure of claim 8, the controller further configured to mitigate an effect of the two-level system (TLS) on the given qubit based on the extrapolated location.

14. The structure of claim 13, wherein the mitigating of the effect of the two-level system (TLS) further comprises retuning a frequency of the two-level system away from a frequency of the given qubit by adjusting one or more voltages of the set of bias voltages.

15. The structure of claim 13, wherein the mitigating of the effect of the two-level system (TLS) further comprises reducing a count of two-level systems proximate the given qubit by adjusting one or more of the voltages of the set of bias voltages.

16. The structure of claim 13, wherein the mitigating of the effect of the two-level system (TLS) further comprises retuning a frequency of the two-level system away from a frequency of the given qubit and reducing a count of two-level systems proximate the given qubit by adjusting one or more voltages of the set of bias voltages.

17. A computer program product, comprising:
one or more tangible computer-readable storage media and program instructions stored on at least one of the one or more tangible computer-readable storage media, the program instructions executable by a processor, the program instructions comprising:
performing an N-dimensional scan of a set of bias voltages, each bias voltage defining a voltage of a corresponding electrode of a set of electrodes, the electrodes being proximate to a given qubit;
determining a sensitivity of a performance of the given qubit to an electronic field generated by each of the electrodes;
extrapolating a probable location of at least one two-level system (TLS) based on the determined sensitivities; and
mitigating an effect of the two-level system (TLS) on the given qubit based on the extrapolated location.

18. The computer program product of claim 17, the program instructions further comprising repeating the performing of the N-dimensional scan of the set of bias voltages, the determining of the sensitivity of the performance of the given qubit, and the extrapolating of the probable location of the at least one two-level system (TLS) based on the determined sensitivities, to generate a statistical distribution of locations of the at least one two-level system (TLS).

19. The computer program product of claim 17, wherein the mitigating of the effect of the two-level system (TLS) further comprises retuning a frequency of the two-level system away from a frequency of the given qubit by adjusting one or more voltages of the set of bias voltages.

20. The computer program product of claim 17, wherein the mitigating of the effect of the two-level system (TLS) further comprises reducing a count of two-level systems proximate the given qubit by adjusting one or more of the voltages of the set of bias voltages.
